(19) United States
(12) Patent Application Publication
(10) Pub. No.: US 2026/0076058 A1
(43) Pub. Date: Mar. 12, 2026

(54) DISPLAY DEVICE AND DISPLAY PANEL

(71) Applicant: LG Display Co., Ltd., Seoul (KR)

(72) Inventors: TaeGyu LEE, Paju-si (KR); YoungWook LEE, Paju-si (KR); Jaeho KIM, Paju-si (KR)

(73) Assignee: LG Display Co., Ltd., Seoul (KR)

(21) Appl. No.: 19/279,501

(22) Filed: Jul. 24, 2025

(30) Foreign Application Priority Data
Sep. 9, 2024 (KR) 10-2024-0122385

(51) Int. Cl. H10K 59/65; H10K 59/35; H10K 59/40; H10K 59/80

(52) U.S. Cl. CPC H10K 59/65; H10K 59/353; H10K 59/40; H10K 59/873; H10K 59/874

(57) ABSTRACT

Aspects of the disclosure relate to a display panel and a display device. The display panel in some examples can include a through hole where an optical electronic device is disposed in a display area, a first rough pattern capable of blocking moisture introduced along a first moisture permeable path in a surrounding area of the through hole, and a second rough pattern disposed to overlap at least a portion of the first rough pattern to block moisture introduced along a second moisture permeable path.

### CROSS-REFERENCE TO RELATED APPLICATION

This application claims priority to Korean Patent Application No. 10-2024-0122385, filed in the Republic of Korea on Sep. 9, 2024, the entirety of which is hereby expressly incorporated by reference for all purposes as if fully set forth herein into the present application.

### BACKGROUND

### Field

Embodiments of the disclosure relate to a display device and a display panel and, more specifically, to a display device and a display panel capable of effectively preventing penetration of moisture through a through hole where an optical electronic device is positioned.

### Description of the Related Art

Representative display devices for displaying an image based on digital data include liquid crystal display (LCD) devices using liquid crystal and organic light emitting display devices using organic light emitting diodes (OLEDs).

Among these display devices, the organic light emitting displays adopt light emitting diodes and thus have fast responsiveness and various merits in contrast ratio, luminous efficiency, brightness, and viewing angle. In this case, the light emitting diode can be implemented with an inorganic material or an organic material.

The organic light emitting display device can include organic light emitting diodes respectively arranged in a plurality of subpixels disposed on a display panel and can cause the organic light emitting diodes to emit light by controlling the current flowing to the organic light emitting diodes, thereby displaying images while controlling the brightness of each subpixel.

With advances in technology, the display device can provide a capture function and various detection functions in addition to an image display function. To this end, the display device includes an optical electronic device (also referred to as a light receiving device or sensor), such as a camera and a detection sensor.

Since the optical electronic device receives light from the front of the display device, it should be installed where light reception is easy. Accordingly, research is being conducted to form a through hole in the active area where the subpixel is formed and to place an optical electronic device inside the through hole.

As such, it can be called a hole-in active area (HiAA), considering that a through hole is present inside the active area for placing the optical electronic device.

However, if moisture enters the through hole where the optical electronic device is positioned or from the outside, the performance of the light emitting element constituting the subpixel can deteriorate.

### BRIEF SUMMARY OF THE DISCLOSURE

Thus, the inventors of the disclosure have invented a display device and a display panel capable of effectively preventing moisture from entering through the through hole or from the outside.

Embodiments of the disclosure can provide a display device and a display panel capable of preventing moisture from entering through a first moisture permeable path by a disconnected structure that cuts a light emitting layer formed between a through hole and an active area.

Embodiments of the disclosure can also provide a display device and a display panel capable of preventing moisture from entering through a second moisture permeable path using a touch sensor metal on an encapsulation layer.

A display device according to embodiments of the disclosure can comprise a display panel including a through hole in a display area, an optical electronic device positioned to at least partially overlap the through hole, and a driving circuit controlling the display panel. The display panel can include a first rough pattern capable of blocking moisture introduced along a first moisture permeable path in a surrounding area of the through hole, and a second rough pattern disposed to overlap at least a portion of the first rough pattern to block moisture introduced along a second moisture permeable path.

A display panel according to embodiments of the disclosure can comprise a through hole where an optical electronic device is disposed in a display area, a first rough pattern capable of blocking moisture introduced along a first moisture permeable path in a surrounding area of the through hole, and a second rough pattern disposed to overlap at least a portion of the first rough pattern to block moisture introduced along a second moisture permeable path.

According to an embodiments of the disclosure, it is possible to effectively prevent or minimize moisture from entering through the through hole or from the outside.

According to embodiments of the disclosure, it is possible to prevent or minimize moisture from entering through a first moisture permeable path by a disconnected structure that cuts a light emitting layer formed between a through hole and an active area.

According to an embodiment of the disclosure, it is possible to prevent or minimize moisture from entering through a second moisture permeable path using a touch sensor metal on an encapsulation layer.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a view illustrating a display device according to embodiments of the disclosure;

FIG. 2 is a view schematically illustrating a system configuration of a display device according to embodiments of the disclosure;

FIG. 3 is a view illustrating an example equivalent circuit of a subpixel in a display panel according to embodiments of the disclosure;

FIG. 4 is a view illustrating a subpixel arrangement in three areas included in a display area in a display panel according to embodiments of the disclosure;

FIG. 5 is an example view illustrating a cross section of a display area in a display panel according to embodiments of the disclosure;

FIG. 6 is a view illustrating a planar structure of an optical area in a display panel according to embodiments of the disclosure;

FIG. 7 is a view illustrating a cross section of an optical area in a display panel according to embodiments of the disclosure;

FIG. 8 is a view illustrating a moisture permeable path of moisture introduced along a first rough pattern in a display panel according to embodiments of the disclosure;

FIG. 9 is a view schematically illustrating a structure of a second rough pattern for blocking moisture introduced through a second moisture permeable path in a display panel according to embodiments of the disclosure;

FIGS. 10 to 13 are views illustrating a process of forming a second rough pattern in a display panel according to embodiments of the disclosure;

FIG. 14 is a view illustrating an example of another structure of an optical area in a display panel according to embodiments of the disclosure; and

FIG. 15 is a view schematically illustrating another structure of a second rough pattern for blocking moisture introduced through a second moisture permeable path in a display panel according to embodiments of the disclosure.

### DETAILED DESCRIPTION OF THE EMBODIMENTS

Hereinafter, some embodiments of the disclosure will be described in detail with reference to example drawings. In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the disclosure will be described in detail with reference to the accompanying drawings. All the components of each display device according to all embodiments of the disclosure are operatively coupled and configured.

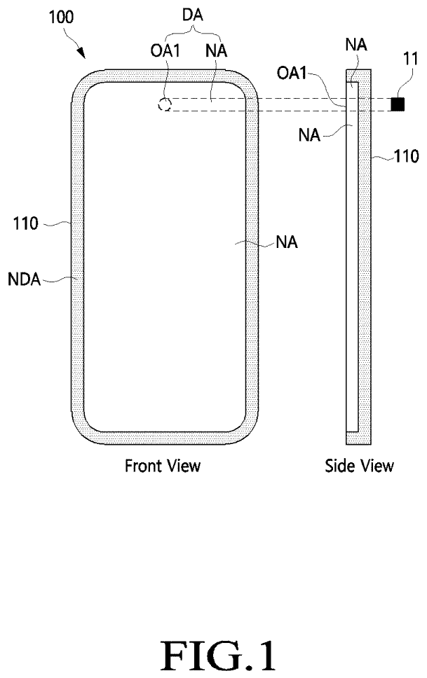

FIG. 1 is a view illustrating a display device according to embodiments of the disclosure.

Referring to FIG. 1, a display device 100 according to embodiments of the disclosure can include a display panel 110 for displaying an image and one or more optical electronic devices 11.

The display panel 110 can include a display area DA in which images are displayed and a non-display area NDA in which no image is displayed. In this case, the display area DA can also be referred to as an active area.

A plurality of subpixels can be disposed in the display area DA, and various signal lines for driving the plurality of subpixels can be disposed in the display area AA.

The non-display area NDA can be an area outside the display area DA. As an example, the non-display area NDA may extend from the display area DA. As an example, the non-display area NDA may fully or partially surround the display area DA, without being limited thereto. In the non-display area NDA, various signal lines can be disposed, and various driving circuits can be connected thereto. The non-display area NDA can be bent to be invisible from the front or can be covered by a case or may be flat without being bent, without being limited thereto. The non-display area NDA is also referred to as a bezel or a bezel area.

In the display device 100 according to embodiments of the disclosure, one or more optical electronic devices 11 are electronic components positioned under (side opposite to the viewing surface) the display panel 110.

Light enters the front surface (viewing surface) of the display panel 110 and passes through the display panel 110 to one or more optical electronic devices 11 positioned under the display panel 110 (opposite to the viewing surface).

The one or more optical electronic devices 11 can be devices that receive the light transmitted through the display panel 110 and perform a predetermined function according to the received light. For example, the one or more optical electronic devices 11 can include one or more of a capture device, such as a camera (image sensor), and a detection sensor, such as a proximity sensor and an illuminance sensor.

The display area DA in the display panel 110 according to embodiments of the disclosure can include the normal area NA and one or more optical areas OA1 and OA2.

The one or more optical areas OA1 and OA2 can be areas overlapping the one or more optical electronic devices 11.

The display area DA can include the normal area NA and the first optical area OA1. At least a portion of the first optical area OA1 can overlap the first optical electronic device 11.

In the display device 100 according to embodiments of the disclosure, if the first optical electronic device 11 that is not exposed to the outside and is hidden in a lower portion of the display panel 110 is a camera, the display device 100 according to embodiments of the disclosure can be referred to as a display to which under display camera (UDC) technology has been applied.

Accordingly, the display device 100 according to embodiments of the disclosure does not require a notch or camera hole for camera exposure to be formed in the display panel 110, thereby preventing a reduction in the display area DA.

Thus, as there is no need to form a notch or camera hole for exposure of the camera in the display panel 110, the size of the bezel area can be reduced, and design restrictions can be freed, thereby increasing the degree of freedom in design.

In the display device 100 according to embodiments of the disclosure, although one or more optical electronic devices 11 are positioned to be hidden behind the display panel 110, one or more optical electronic devices 11 should be able to normally perform predetermined functions by normally receiving light.

Further, in the display device 100 according to embodiments of the disclosure, although one or more optical electronic devices 11 are positioned to be hidden behind the display panel 110 and are positioned to overlap the display area DA, the one or more optical areas OA1 and OA2 overlapping the one or more optical electronic devices 11 in the display area DA should be capable of normal image display.

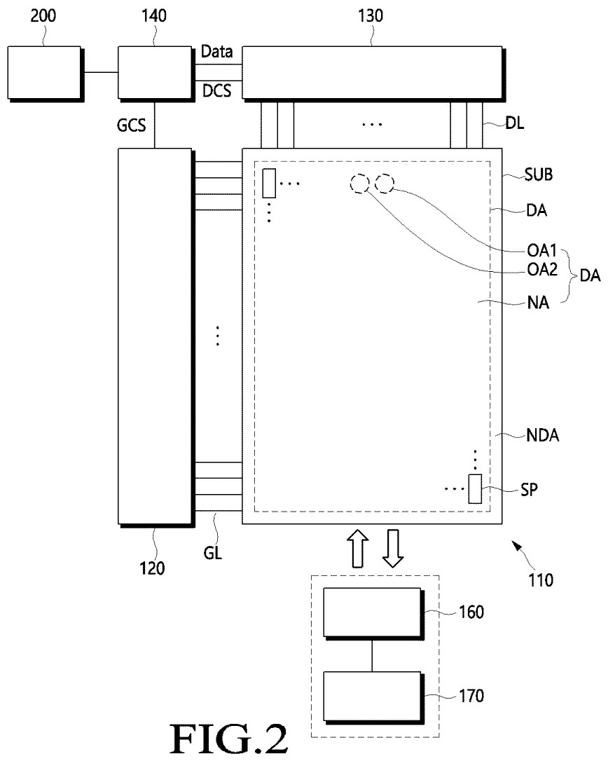

FIG. 2 is a view schematically illustrating a system configuration of a display device according to embodiments of the disclosure.

Referring to FIG. 2, a display device 100 according to embodiments of the disclosure can include a display panel 110 and display driving circuits, as components for displaying images.

The display driving circuits are circuits for driving the display panel 110 and can include a gate driving circuit 120, a data driving circuit 130, and a display controller 140.

The display panel 110 can include a display area DA in which images are displayed and a non-display area NDA in which no image is displayed. The non-display area NDA can be an outer area of the display area DA and be referred to as a bezel area.

The whole or part of the non-display area NDA can be an area visible from the front surface of the display device 100 or an area that is bent and not visible from the front surface of the display device 100.

The display panel 110 can include a substrate SUB and a plurality of subpixels SP disposed on the substrate SUB. The display panel 110 can further include various types of signal lines to drive the plurality of subpixels SP.

The display device 100 according to embodiments of the disclosure can be a liquid crystal display device or a self-emission display device in which the display panel 110 emits light by itself. When the display device 100 according to the embodiments of the disclosure is a self-emissive display device, each of the plurality of subpixels SP can include a light emitting element.

For example, the display device 100 according to embodiments of the disclosure can be an organic light emitting diode display in which the light emitting element is implemented as an organic light emitting diode (OLED). As another example, the display device 100 according to embodiments of the disclosure can be an inorganic light emitting display device in which the light emitting element is implemented as an inorganic material-based light emitting diode. As another example, the display device 100 according to embodiments of the disclosure can be a quantum dot display device in which the light emitting element is implemented as a quantum dot which is self-emission semiconductor crystal.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors.

For example, various types of signal lines can include a plurality of data lines DL transferring data signals (also referred to as data voltages or image signals) and a plurality of gate lines GL transferring gate signals (also referred to as scan signals).

The plurality of data lines DL and the plurality of gate lines GL can cross each other. Each of the plurality of data lines DL can be disposed while extending in a first direction. Each of the plurality of gate lines GL can be disposed while extending in a second direction.

Here, the first direction can be a column direction and the second direction can be a row direction. The first direction can be the row direction, and the second direction can be the column direction.

The data driving circuit 130 is a circuit for driving the plurality of data lines DL, and can output data signals to the plurality of data lines DL. The gate driving circuit 120 is a circuit for driving the plurality of gate lines GL, and can output gate signals to the plurality of gate lines GL.

The display controller 140 is a device for controlling the data driving circuit 130 and the gate driving circuit 120 and can control driving timings for the plurality of data lines DL and driving timings for the plurality of gate lines GL.

The display controller 140 can supply a data driving control signal DCS to the data driving circuit 130 to control the data driving circuit 130 and can supply a gate driving control signal GCS to the gate driving circuit 120 to control the gate driving circuit 120.

The display controller 140 can receive input image data from the host system 200 and supply image data Data to the data driving circuit 130 based on the input image data.

The data driving circuit 130 can supply data signals to the plurality of data lines DL according to the driving timing control of the display controller 140.

The data driving circuit 130 can receive digital image data Data from the display controller 140 and can convert the received image data Data into analog data signals and output the analog data signals to the plurality of data lines DL.

The gate driving circuit 120 can supply gate signals to the plurality of gate lines GL according to the timing control of the display controller 140. The gate driving circuit 120 can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit 130 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110.

The gate driving circuit 120 can be connected with the display panel 110 by TAB method or connected to a bonding pad of the display panel 110 by a COG or COP method or can be connected with the display panel 110 according to a COF method.

Alternatively, the gate driving circuit 120 can be formed in a gate in panel (GIP) type, in the non-display area NDA of the display panel 110. The gate driving circuit 120 can be disposed on the substrate or can be connected to the substrate. In other words, the gate driving circuit 120 that is of a GIP type can be disposed in the non-display area NDA of the substrate. The gate driving circuit 120 that is of a chip-on-glass (COG) type or chip-on-film (COF) type can be connected to the substrate.

Meanwhile, at least one of the data driving circuit 130 and the gate driving circuit 120 can be disposed in the display area DA of the display panel 110. For example, at least one of the data driving circuit 130 and the gate driving circuit 120 can be disposed not to overlap the subpixels SP or to overlap all or some of the subpixels SP.

The data driving circuit 130 can be connected to one side (e.g., an upper or lower side) of the display panel 110. Depending on the driving scheme or the panel design scheme, data driving circuits 130 can be connected with both the sides (e.g., both the upper and lower sides) of the display panel 110, or two or more of the four sides of the display panel 110.

The gate driving circuit 120 can be connected to one side (e.g., a left or right side) of the display panel 110. Depending on the driving scheme or the panel design scheme, gate driving circuits 120 can be connected with both the sides (e.g., both the left and right sides) of the display panel 110, or two or more of the four sides of the display panel 110.

The display controller 140 can be implemented as a separate component from the data driving circuit 130, or the display controller 140 and the data driving circuit 130 can be integrated into an integrated circuit (IC).

The display controller 140 can be a timing controller used in typical display technology, a control device that can perform other control functions as well as the functions of the timing controller, or a control device other than the timing controller, or can be a circuit in the control device. The display controller 140 can be implemented as various circuits or electronic components, such as an integrated circuit (IC), a field programmable gate array (FPGA), an application specific integrated circuit (ASIC), or a processor.

The display controller 140 can be mounted on a printed circuit board or a flexible printed circuit and can be electrically connected with the data driving circuit 130 and the gate driving circuit 120 through the printed circuit board or the flexible printed circuit.

The display controller 140 can transmit/receive signals to/from the data driving circuit 130 according to one or more predetermined interfaces. The interface can include, e.g., a low voltage differential signaling (LVDS) interface, an EPI interface, and a serial peripheral interface (SP).

To provide a touch sensing function as well as an image display function, the display device 100 according to embodiments of the disclosure can include a touch sensor and a touch circuit that senses the touch sensor to detect whether a touch occurs by a touch object, such as a finger or pen, or the position of the touch.

The touch circuit can include a touch driving circuit 160 that drives and senses the touch sensor and generates and outputs touch sensing data and a touch controller 170 that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit 160.

The touch sensor can be present in a touch panel form outside the display panel 110 or can be present inside the display panel 110. When the touch panel, in the form of a touch panel, exists outside the display panel 110, the touch panel is referred to as an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate SUB, together with signal lines and electrodes related to display driving, during the manufacturing process of the display panel 110.

The touch driving circuit 160 can supply a touch driving signal to at least one of the plurality of touch electrodes and can sense at least one of the plurality of touch electrodes to generate touch sensing data.

The touch circuit can perform touch sensing in a self-capacitance sensing scheme or a mutual-capacitance sensing scheme.

When the touch circuit performs touch sensing in the self-capacitance sensing scheme, the touch circuit can perform touch sensing based on capacitance between each touch electrode and the touch object (e.g., finger or pen).

According to the self-capacitance sensing scheme, each of the plurality of touch electrodes can serve both as a driving touch electrode and as a sensing touch electrode. The touch driving circuit 160 can drive all or some of the plurality of touch electrodes and sense all or some of the plurality of touch electrodes.

When the touch circuit performs touch sensing in the mutual-capacitance sensing scheme, the touch circuit can perform touch sensing based on capacitance between the touch electrodes.

According to the mutual-capacitance sensing scheme, the plurality of touch electrodes are divided into driving touch electrodes and sensing touch electrodes. The touch driving circuit 160 can drive the driving touch electrodes and sense the sensing touch electrodes.

The touch driving circuit 160 and the touch controller 170 included in the touch circuit can be implemented as separate devices or as a single device. The touch driving circuit 160 and the data driving circuit 130 can be implemented as separate devices or as a single device.

The display device 100 can further include a power supply circuit for supplying various types of power to the display driver integrated circuit and/or the touch circuit.

The display device 100 according to embodiments of the disclosure can be a mobile terminal such as a smartphone, a tablet, or the like, or a monitor or a television (TV) of various sizes, but is not limited thereto, and can be a display of various types and various sizes capable of displaying information or an image.

As described above, the display area DA in the display panel 110 can include the normal area NA and one or more optical areas OA1 and OA2.

The normal area NA and one or more optical areas OA1 and OA2 are areas capable of displaying an image. However, the normal area NA is an area where a light transmission structure is not required to be formed, and one or more optical areas OA1 and OA2 are areas in which a light transmission structure is to be formed.

As described above, the display area DA in the display panel 110 can include one or more optical areas OA1 and OA2 together with the normal area NA, but for convenience of description, it is assumed that the display area DA includes both the first optical area OA1 and the second optical area OA2.

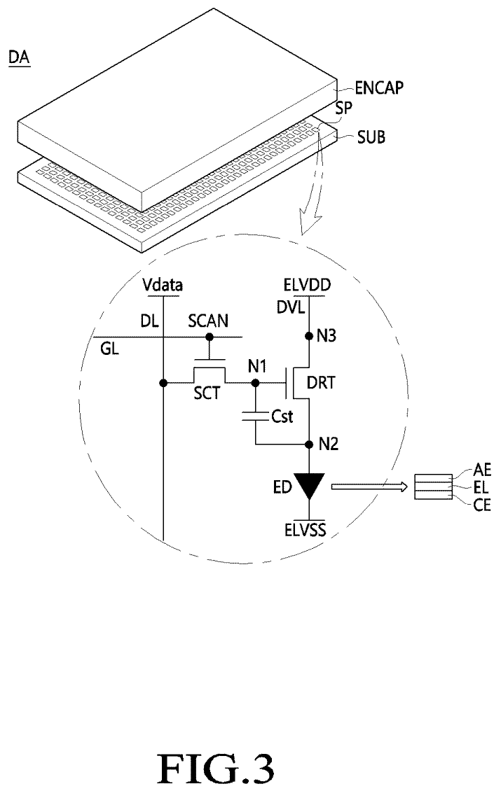

FIG. 3 is a view illustrating an example equivalent circuit of a subpixel in a display panel according to embodiments of the disclosure.

Referring to FIG. 3, each subpixel SP disposed in the normal area NA, the first optical area OA1, and the second optical area OA2 included in the display area OA of the display panel 110 according to embodiments of the disclosure can include an light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame.

The driving transistor DRT can include the first node N1 to which the data voltage Vdata can be applied, a second node N2 electrically connected with the light emitting element ED, and a third node N3 to which a driving voltage ELVDD is applied from a driving voltage line DVL. The first node N1 in the driving transistor DRT can be a gate node, the second node N2 can be a source node or a drain node, and the third node N3 can be the drain node or the source node.

The light emitting element ED can include an anode electrode AE, a light emitting layer EL, and a cathode electrode CE. The anode electrode AE can be a pixel electrode disposed in each subpixel SP and be electrically connected to the second node N2 of the driving transistor DRT of each subpixel SP. The cathode electrode CE can be a common electrode commonly disposed in the plurality of subpixels SP, and a base voltage ELVSS can be applied thereto.

For example, the anode electrode AE can be a pixel electrode, and the cathode electrode CE can be a common electrode. Conversely, the anode electrode AE can be a common electrode, and the cathode electrode CE can be a pixel electrode. Hereinafter, for convenience of description, it is assumed that the anode electrode AE is a pixel electrode and the cathode electrode CE is a common electrode.

For example, the light emitting element ED can be an organic light emitting diode (OLED), an inorganic light emitting diode, or a quantum dot light emitting element. In this case, when the light emitting element ED is an organic light emitting diode, the light emitting layer EL of the light emitting element ED can include an organic light emitting layer including an organic material. The scan transistor SCT can be on/off controlled by a scan signal SCAN, which is a gate signal, applied via the gate line GL and be electrically connected between the first node N1 of the driving transistor DRT and the data line DL.

The storage capacitor Cst can be electrically connected between the first node N1 and second node N2 of the driving transistor DRT.

Each subpixel SP can have a 2T (transistor) 1C (capacitor) structure which includes two transistors DRT and SCT and one capacitor Cst as shown in FIG. 3 and, in some cases, each subpixel SP can further include one or more transistors or one or more capacitors.

The capacitor Cst can be an external capacitor intentionally designed to be outside the driving transistor DRT, but not a parasite capacitor (e.g., Cgs or Cgd) which is an internal capacitor that can be present between the first node N1 and the second node N2 of the driving transistor DRT.

Each of the driving transistor DRT and the scan transistor SCT can be an n-type transistor or a p-type transistor. As an example, the driving transistor DRT and the scan transistor SCT may be of the same type or different types.

Since the circuit elements (particularly, the light emitting element ED) in each subpixel SP are vulnerable to external moisture or oxygen, an encapsulation layer ENCAP can be disposed on the display panel 110 to prevent penetration of external moisture or oxygen into the circuit elements (particularly, the light emitting element ED). The encapsulation layer ENCAP can be disposed to cover the light emitting elements ED.

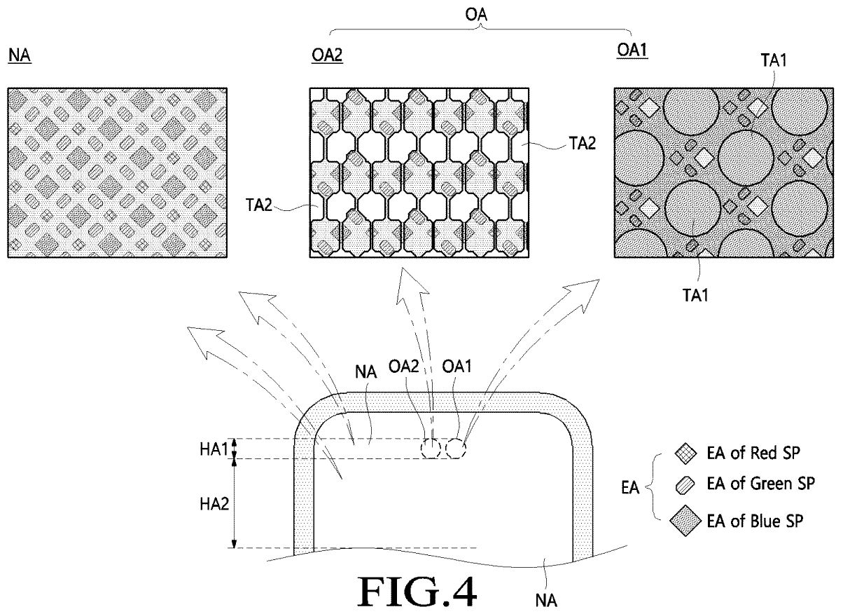

FIG. 4 is a view illustrating a subpixel arrangement in three areas included in a display area in a display panel according to embodiments of the disclosure.

Referring to FIG. 4, in the display panel 110 according to embodiments of the disclosure, a plurality of subpixels SP can be disposed in the normal area NA, the first optical area OA1, and the second optical area OA2 included in the display area DA.

For example, the plurality of subpixels SP can include a red subpixel Red SP emitting red light, a green subpixel Green SP emitting green light, and a blue subpixel Blue SP emitting blue light.

Accordingly, each of the normal area NA, the first optical area OA1, and the second optical area OA2 can include emission areas EA of the red subpixels Red SP, emission areas EA of the green subpixels Green SP, and emission areas EA of the blue subpixels Blue SP.

The normal area NA may not include a light transmission structure, but can include light emission areas EA. As an example, the normal area NA may also include a light emission area. As an example, the normal area NA may include a light emission area smaller than equal to or greater than that of the first optical area OA1 and the second optical area OA2, without being limited thereto.

However, the first optical area OA1 and the second optical area OA2 should not only include the emission areas EA, but also include a light transmission structure.

Accordingly, the first optical area OA1 can include emission areas EA and first transmissive areas TA1, and the second optical area OA2 can include emission areas EA and second transmissive areas TA2.

The emission areas EA and the transmissive areas TA1 and TA2 can be distinguished based on whether they can transmit light. In other words, the emission areas EA can be areas through which light cannot pass, and the transmissive areas TA1 and TA2 can be areas through which light can pass.

Further, the emission areas EA and the transmissive areas TA1 and TA2 can be distinguished depending on the presence or absence of a specific metal layer CE. For example, a cathode electrode CE can be formed in the emission areas EA, and a cathode electrode CE may not be formed in the transmissive areas TA1 and TA2. A light shield layer can be formed in the emission areas EA, and a light shield layer may not be formed in the transmissive areas TA1 and TA2.

Since the first optical area OA1 includes first transmissive areas TA1 and the second optical area OA2 includes second transmissive areas TA2, both the first optical area OA1 and the second optical area OA2 are areas through which light can pass.

The transmittance (degree of transmission) of the first optical area OA1 and the transmittance (degree of transmission) of the second optical area OA2 can be the same.

In this case, the first transmissive area TA1 of the first optical area OA1 and the second transmissive area TA2 of the second optical area OA2 can have the same shape or size. Alternatively, even though the first transmissive area TA1 of the first optical area OA1 and the second transmissive area TA2 of the second optical area OA2 have different shapes or sizes, the ratio of the first transmissive area TA1 in the first optical area OA1 and the ratio of the second transmissive area TA2 in the second optical area OA2 can be the same.

Alternatively, the transmittance (degree of transmission) of the first optical area OA1 and the transmittance (degree of transmission) of the second optical area OA2 can be different from each other.

In this case, the first transmissive area TA1 of the first optical area OA1 and the second transmissive area TA2 of the second optical area OA2 can have different shapes or sizes. Alternatively, even though the first transmissive area TA1 of the first optical area OA1 and the second transmissive area TA2 of the second optical area OA2 have the same shape or size, the ratio of the first transmissive area TA1 in the first optical area OA1 and the ratio of the second transmissive area TA2 in the second optical area OA2 can be different from each other.

For example, if the first optical electronic device 11 overlapping the first optical area OA1 is a camera and the second optical electronic device 12 overlapping the second optical area OA2 is a detection sensor, the camera can require a larger amount of light than the detection sensor.

Therefore, the transmittance (degree of transmission) of the first optical area OA1 can be higher than the transmittance (degree of transmission) of the second optical area OA2.

In this case, the first transmissive area TA1 of the first optical area OA1 can have a size larger than that of the second transmissive area TA2 of the second optical area OA2. Alternatively, even though the first transmissive area TA1 of the first optical area OA1 and the second transmissive area TA2 of the second optical area OA2 have the same size, a ratio of the first transmissive area TA1 in the first optical area OA1 can be larger than a ratio of the second transmissive area TA2 in the second optical area OA2.

Hereinafter, for convenience of description, the case where the transmittance (degree of transmission) of the first optical area OA1 is higher than the transmittance (degree of transmission) of the second optical area OA2 is described as an example.

Further, in embodiments of the disclosure, the transmissive areas TA1 and TA2 can be referred to as transparent areas, and the transmittance can be referred to as transparency.

Further, in embodiments of the disclosure, it is assumed that the first optical area OA1 and the second optical area OA2 are positioned at the upper end of the display area DA of the display panel 110 and are disposed side by side. As an example, the first optical area OA1 and the second optical area OA2 may be positioned at any position (e.g., lower end, left end, right end, center portion, corner portion, etc.) of the display area DA of the display panel 110. As an example, the first optical area OA1 and the second optical area OA2 may be positioned at different positions of the display area DA of the display panel, without being limited thereto.

A horizontal display area where the first optical area OA1 and the second optical area OA2 are disposed is referred to as a first horizontal display area HA1, and a horizontal display area where the first optical area OA1 and the second optical area OA2 are not disposed is referred to as a second horizontal display area HA2.

The first horizontal display area HA1 can include a normal area NA, a first optical area OA1, and a second optical area OA2. The second horizontal display area HA2 can include only the normal area NA.

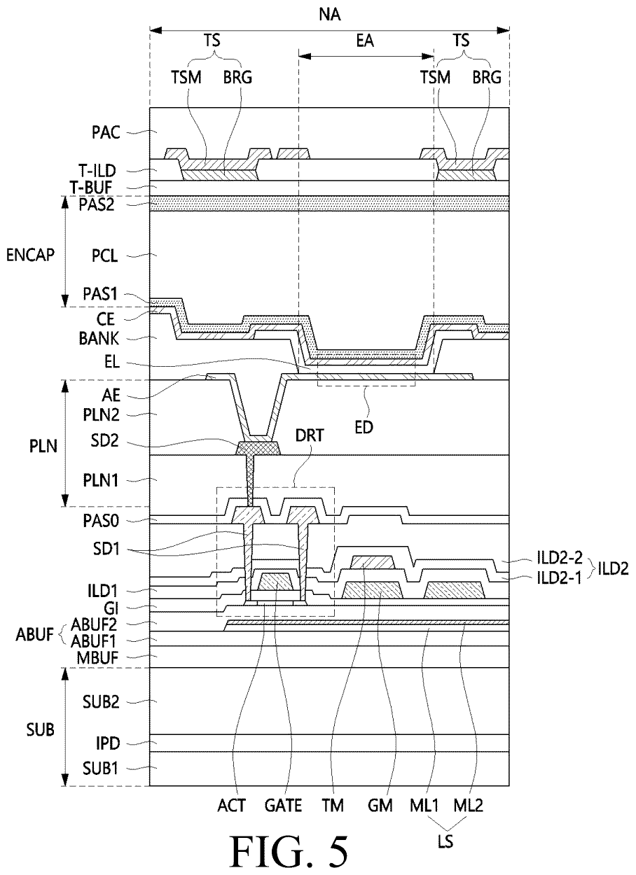

FIG. 5 is an example view illustrating a cross section of a display area in a display panel according to embodiments of the disclosure.

Illustrated here is the normal area NA except for the optical area OA where the optical electronic device11 is disposed.

Referring to FIG. 5, a display panel 110 according to embodiments of the disclosure can include a substrate SUB, a driving transistor DRT, a planarization layer PLN, a light emitting element ED, an encapsulation layer ENCAP, and a touch layer.

The substrate SUB can include a first substrate SUB1, a substrate insulation film IPD, and a second substrate SUB2. The substrate insulation film IPD can be positioned between the first substrate SUB1 and the second substrate SUB2. As an example, the substrate insulation film IPD may be omitted depending on the design. As an example, the substrate SUB may include one single substrate or three or more substrates.

By configuring the substrate SUB with the first substrate SUB1, the substrate insulation film IPD and the second substrate SUB2, it is possible to minimize or prevent moisture penetration.

For example, the first substrate SUB1 and the second substrate SUB2 can be polyimide (PI) substrates. The first substrate SUB1 can be referred to as a primary PI substrate, and the second substrate SUB2 can be referred to as a secondary PI substrate.

On the substrate SUB, various patterns ACT, SD1, and GATE for forming a transistor, such as a driving transistor DRT, various insulation films MBUF, ABUF1, ABUF2, GI, ILD1, ILD2, and PAS0, and various metal patterns TM, GM, ML1, and ML2 can be disposed.

A multi-buffer layer MBUF can be disposed on the second substrate SUB2. A first active buffer layer ABUF1 can be disposed on the multi-buffer layer MBUF.

A first metal layer ML1 and a second metal layer ML2 can be disposed on the first active buffer layer ABUF1. The first metal layer ML1 and the second metal layer ML2 can be a light shield layer LS for shielding light. As an example, the light shield layer LS may include one metal layer or three or more metal layers. As an example, the light shield layer LS may include an opaque material other than metal. As an example, the light shield layer LS may be omitted depending on the design.

A second active buffer layer ABUF2 can be disposed on the first metal layer ML1 and the second metal layer ML2. An active layer ACT of the driving transistor DRT can be disposed on the second active buffer layer ABUF2.

A gate insulation film GI can be disposed while covering the active layer ACT.

A gate electrode GATE of the driving transistor DRT can be disposed on the gate insulation film GI. In this case, in a position different from the position where the driving transistor DRT is formed, a gate material layer GM, together with the gate electrode GATE of the driving transistor DRT, can be disposed on the gate insulation film GI.

The first interlayer insulation film ILD1 can be disposed while covering the gate electrode GATE and the gate material layer GM. A metal pattern TM can be disposed on the first interlayer insulation film ILD1. The metal pattern TM can be located in a position different from the position where the driving transistor DRT is formed.

The second interlayer insulation film ILD2 can be disposed while covering the metal pattern TM on the first interlayer insulation film ILD1.

Two first source-drain electrode patterns SD1 can be disposed on the second interlayer insulation film ILD2. One of the two first source-drain electrode patterns SD1 is the source node of the driving transistor DRT, and the other is the drain node of the driving transistor DRT.

The two first source-drain electrode patterns SD1 can be electrically connected with the two opposite sides, respectively, of the active layer ACT through the contact hole of the second interlayer insulation film ILD2, the first interlayer insulation film ILD1, and the gate insulation film GI.

The second interlayer insulation film ILD2 can include a 2-1th interlayer insulation film ILD2-1 and a 2-2th interlayer insulation film ILD2-2. The 2-1th interlayer insulation film ILD2-1 can be positioned while covering the metal pattern TM. The 2-2th interlayer insulation film ILD2-2 can be positioned on the 2-1th interlayer insulation film ILD2-1.

A portion of the active layer ACT overlapping the gate electrode GATE is a channel area. One of the two first source-drain electrode patterns SD1 can be connected to one side of the channel area in the active layer ACT, and the other one of the two first source-drain electrode patterns SD1 can be connected to the other side of the channel area in the active layer ACT.

A passivation layer PAS0 is disposed while covering the two first source-drain electrode patterns SD1. A planarization layer PLN can be disposed on the passivation layer PAS0.

The planarization layer PLN can include a first planarization layer PLN1 and a second planarization layer PLN2. As an example, the planarization layer PLN may include one planarization layer or three or more planarization layers, without being limited thereto.

The first planarization layer PLN1 can be disposed on the passivation layer PAS0.

A second source-drain electrode pattern SD2 can be disposed on the first planarization layer PLN1. The second source-drain electrode pattern SD2 can be connected with one of the two first source-drain electrode patterns SD1 (corresponding to the second node N2 of the driving transistor DRT in the subpixel SP of FIG. 3) through the contact hole of the first planarization layer PLN1. As an example, the second source-drain electrode pattern SD2 may be omitted depending on the design.

The second planarization layer PLN2 can be disposed while covering the second source-drain electrode pattern SD2. A light emitting element ED can be disposed on the second planarization layer PLN2.

The light emitting element ED can include an anode electrode AE, a light emitting layer EL, and a cathode electrode CE.

The anode electrode AE can be disposed on the second planarization layer PLN2. The anode electrode AE can be electrically connected to the second source-drain electrode pattern SD2 through the contact hole of the second planarization layer PLN2.

The bank BANK can be disposed while covering a portion of the anode electrode AE. A portion of the bank BANK corresponding to the light emitting area EA of the subpixel SP can be opened.

A portion of the anode electrode AE can be exposed through an opening (open portion) of the bank BANK.

A light emitting layer EL can be positioned on a side surface of the bank BANK and the opening (open portion) of the bank BANK. The whole or part of the light emitting layer EL can be positioned between adjacent banks BANK. The light emitting layer EL can include an organic film.

In the opening of the bank BANK, the light emitting layer EL can contact the anode electrode AE. A cathode electrode CE can be disposed on the light emitting layer EL.

An encapsulation layer ENCAP can be disposed on the light emitting element ED.

The encapsulation layer ENCAP can have a single-layer structure or a multi-layer structure. For example, the encapsulation layer ENCAP can include a first encapsulation layer PAS1, a second encapsulation layer PCL, and a third encapsulation layer PAS2.

For example, the first encapsulation layer PAS1 and the third encapsulation layer PAS2 can be inorganic films, and the second encapsulation layer PCL can be an organic layer. Among the first encapsulation layer PAS1, the second encapsulation layer PCL, and the third encapsulation layer PAS2, the second encapsulation layer PCL can be the thickest. Accordingly, the second encapsulation layer PCL can serve as a planarization layer.

The first encapsulation layer PAS1 is also referred to as a first inorganic encapsulation layer. The second encapsulation layer PCL is also referred to as an organic encapsulation layer, and the third encapsulation layer PAS2 is also referred to as a second inorganic encapsulation layer.

The first encapsulation layer PAS1 can be disposed on the cathode electrode CE and be disposed closest to the light emitting element ED. The first encapsulation layer PAS1 can be formed of an inorganic insulating material capable of low-temperature deposition. For example, the first encapsulation layer PAS1 can be silicon nitride (SiNx), silicon oxide (SiOx), silicon oxynitride (SiON), or aluminum oxide (Al2O3). Since the first encapsulation layer PAS1 is deposited in a low temperature atmosphere, the first encapsulation layer PAS1 can prevent damage to the light emitting layer EL including an organic material vulnerable to a high temperature atmosphere during the deposition process.

The second encapsulation layer PCL can have a smaller area than the first encapsulation layer PAS1. In this case, the second encapsulation layer PCL can be formed to expose two opposite ends of the first encapsulation layer PAS1. The second encapsulation layer PCL serves as a buffer for relieving stress between layers due to bending of the display device 100 and can also serve to enhance planarization performance.

For example, the second encapsulation layer PCL can be an acrylic resin, an epoxy resin, polyimide, polyethylene, or silicon oxycarbon (SiOC) and be formed of an organic insulating material. For example, the second encapsulation layer PCL can be formed through an inkjet scheme.

The third encapsulation layer PAS2 can be formed on the second encapsulation layer PCL to cover the respective upper surfaces and side surfaces of the second encapsulation layer PCL and the first encapsulation layer PAS1. The third encapsulation layer PAS2 can minimize or block external moisture or oxygen from penetrating into the first encapsulation layer PAS1 and the second encapsulation layer PCL.

For example, the third encapsulation layer PAS2 can be formed of an inorganic insulating material such as silicon nitride (SiNx), silicon oxide (SiOx), silicon oxynitride (SiON), or aluminum oxide (Al2O3).

Meanwhile, the display device 100 of the disclosure can have a touch sensor TS formed on the encapsulation layer ENCAP for detecting a touch of the user's finger or a pen.

When the touch sensor TS is of a type embedded in the display panel 110, the touch sensor TS can be disposed on the encapsulation layer ENCAP. The touch sensor structure is described below in detail.

A touch buffer film T-BUF can be disposed on the encapsulation layer ENCAP.

A touch sensor TS can be disposed on the touch buffer film T-BUF.

The touch sensor TS can include a touch sensor metal TSM and a bridge metal BRG positioned on different layers.

The touch sensor metal TSM and the bridge metal BRG can be formed of a triple structure of Ti/Al/Ti.

A touch interlayer insulation film T-ILD can be disposed between the touch sensor metal TSM and the bridge metal BRG.

The touch interlayer insulation film T-ILD can be formed of an inorganic material silicon nitride SiNx or an organic material of silicon oxide SiOx. In this case, to enhance touch performance, the touch interlayer insulation film T-ILD can be formed of an organic material of silicon oxide SiOx.

For example, the touch sensor TS can include a first touch sensor metal, a second touch sensor metal, and a third touch sensor metal that are disposed adjacent to each other.

The third touch sensor metal is disposed between the first touch sensor metal and the second touch sensor metal and, when the first touch sensor metal and the second touch sensor metal are electrically connected to each other, the first touch sensor metal TSM and the second touch sensor metal can be electrically connected to each other through the bridge metal BRG positioned on a different layer.

The bridge metal BRG can be insulated from the third touch sensor metal by the touch interlayer insulation film T-ILD.

When the touch sensor TS is formed on the display panel 110, moisture can be generated from the chemical solution (e.g., developer or etchant) used in the process.

By disposing the touch sensor TS on the touch buffer layer T-BUF, it is possible to minimize or prevent a chemical solution or moisture from penetrating into the light emitting layer EL including an organic material during the manufacturing process of the touch sensor TS.

Thus, the touch buffer film T-BUF can prevent damage to the light emitting layer EL vulnerable to chemicals or moisture.

The touch buffer film T-BUF can be formed of an organic insulation material with a low permittivity and formed at a low temperature which is not more than a predetermined temperature (e.g., 100° C.) to minimize or prevent damage to the light emitting layer EL containing the organic material vulnerable to high temperature. For example, the touch buffer film T-BUF can be formed of an acrylic-based, epoxy-based, or siloxane-based material.

As the display device 100 is bent, the encapsulation layer ENCAP can be damaged, and the touch sensor metal TSM positioned on the touch buffer layer T-BUF can be broken. Even when the display device 100 is bent, the touch buffer film T-TBUF formed of an organic insulating material and having planarization capability can minimize or prevent damage to the encapsulation layer ENCAP and/or breakage of the touch sensor metal TSM or bridge metal BRG.

A protective layer PAC can be disposed while covering the touch sensor TS. The protective layer PAC can be an organic insulation film.

In the display panel 110, moisture entering through the through hole TH can be introduced through the light emitting layer EL to damage the light emitting element ED.

Further, moisture generated in the process of forming the touch sensor TS or introduced from the outside can flow into the encapsulation layer ENCAP through the upper touch interlayer insulation film T-ILD and the touch buffer film T-BUF to damage the light emitting element ED.

The display panel 110 of the disclosure effectively blocks the first moisture permeable path through which moisture is introduced through the light emitting layer EL and the second moisture permeable path through which moisture is introduced from the upper portion of the encapsulation layer ENCAP, thereby enhancing moisture blocking reliability.

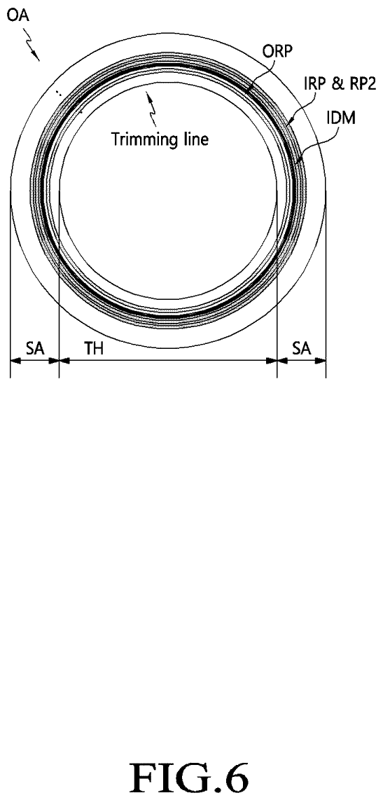

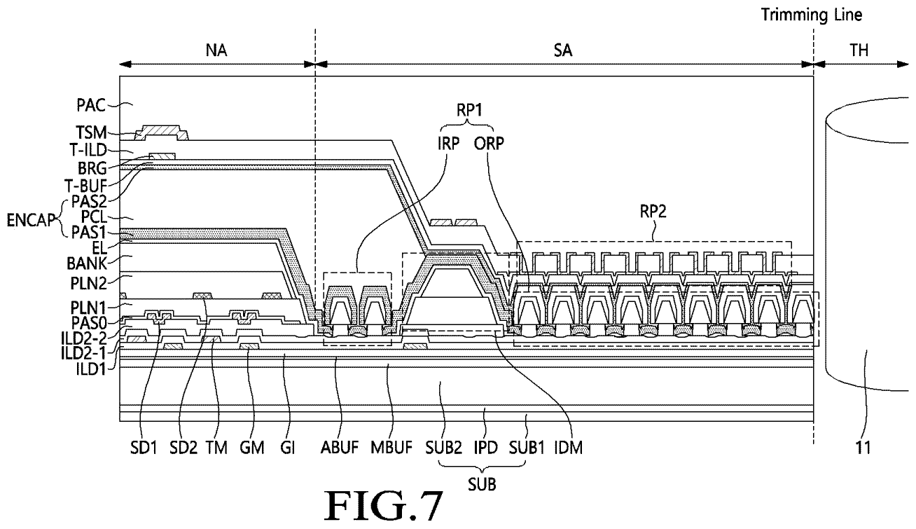

FIG. 6 is a view illustrating a planar structure of an optical area in a display panel according to embodiments of the disclosure. FIG. 7 is a view illustrating a cross section of an optical area.

Referring to FIGS. 6 and 7, in the display panel 110 according to embodiments of the disclosure, an optical area OA can be disposed in the display area DA.

Subpixels can be disposed around the optical area OA. Alternatively, a subpixel for displaying an image may not be positioned in the optical area OA.

The optical area OA can be one of the first optical area OA1 and the second optical area OA2 described above.

The optical area OA includes a through hole TH and a surrounding area SA around the through hole TH.

A rough pattern RP for minimizing or preventing moisture penetration can be positioned in the surrounding area SA.

The through hole TH can be formed by removing the substrate along a trimming line. The through hole TH can have a circular shape, but can have various shapes such as an ellipse, a square, a hexagon, or an octagon.

The rough pattern RP can include a first rough pattern RP1 for blocking a first moisture permeable path through which moisture is introduced along the light emitting layer EL, and a second rough pattern RP2 for blocking moisture introduced through the encapsulation layer ENCAP from the upper portion.

The first rough pattern RP1 can include an inner side rough pattern IRP close to the normal area NA and an outer side rough pattern ORP close to the through hole TH.

Further, an inner dam IDM that separates the inner side rough pattern IRP and the outer side rough pattern ORP from each other between the inner side rough pattern IRP and the outer side rough pattern ORP can be positioned in the surrounding area SA.

An outer dam disposed in the surrounding area SA can be further disposed outside the inner side rough pattern IRP. The outer dam can be disposed to minimize or prevent the encapsulation layer ENCAP from overflowing out of the normal area NA.

The shape of the inner dam IDM corresponds to the shape of the through hole TH and has a closed curve shape surrounding the through hole TH. The inner dam IDM and the through hole TH can have different closed loop shapes or can have the same closed loop shape but have different sizes. For example, the inner dam IDM and the through hole TH can have a concentric shape and be spaced apart from each other by a predetermined interval.

The first rough pattern RP1 has a closed loop shape corresponding to the shape of the through hole TH and surrounding the through hole TH. The first rough pattern RP can have a closed loop shape different from that of the through hole TH or can have a closed loop shape having the same shape but different sizes from that of the through hole TH.

Here, a case where the first rough pattern RP1 and the through hole TH have the same shape and are spaced apart from each other by a predetermined interval is illustrated.

The subpixel disposed in the normal area NA can include a light emitting element ED. When the light emitting element ED is an organic light emitting element, a light emitting layer EL can be positioned in the normal area NA, and the light emitting layer EL can be an organic light emitting layer including an organic material.

The organic light emitting layer can be disposed up to at least a partial area of the optical area OA.

On the other hand, when moisture penetrates into the organic light emitting layer through the first moisture permeable path, a defect can occur in the light emitting element ED, causing, e.g., darkening of the subpixel. In this case, moisture can penetrate from the area where the through hole TH is positioned.

Further, moisture introduced from the through hole TH or the outside can penetrate into the normal area NA through the touch interlayer insulation film T-ILD, the touch buffer layer T-BUF, and the encapsulation layer ENCAP.

As such, in order to block moisture introduced through the second moisture permeable path, the second rough pattern RP2 can be formed on the upper portion of the outer side rough pattern ORP constituting the first rough pattern RP1.

Accordingly, the second rough pattern RP2 can minimize or prevent moisture introduced from the through hole TH or the like from reaching the light emitting element ED positioned in the normal area NA through the touch interlayer insulating film T-ILD, the touch buffer film T-BUF, and the encapsulation layer ENCAP.

The second rough pattern RP2 has a closed loop shape corresponding to the shape of the through hole TH and surrounding the through hole TH. The second rough pattern RP2 can have a closed loop shape different from that of the through hole TH or can have a closed loop shape having the same shape but different sizes from that of the through hole TH.

Here, a case where the second rough pattern RP2 and the through hole TH have the same shape and are spaced apart from each other by a predetermined interval is illustrated.

The optical area OA can include the through hole TH and the surrounding area SA, and the normal area NA can be positioned outside the surrounding area SA.

In the through hole TH, an optical electronic device 11 positioned under the display panel 110 and at least partially overlapping the through hole TH can be positioned.

A first rough pattern RP1 including an inner side rough pattern IRP and an outer side rough pattern ORP is positioned inside and outside the inner dam IDM.

The first rough pattern RP1 can include a mountain including an insulation layer (e.g., ILD1, ILD2-1, or ILD2-2) and a valley resultant from removing at least a portion of the insulation layer. Here, the mountain can also be referred to as a mountain part, and the valley can also be referred to as a valley part.

The light emitting layer EL can be positioned in at least a partial area of the first rough pattern RP1. The light emitting layer EL can be an organic light emitting layer including an organic material.

The light emitting layer EL can extend from the normal area NA to at least a partial area of the surrounding area SA. The light emitting layer EL is discontinuously positioned in the inner side rough pattern IRP and the outer side rough pattern ORP.

Thus, even when the moisture introduced from the through hole TH permeates to the light emitting layer EL positioned in the surrounding area SA, the moisture does not penetrate to the light emitting layer EL positioned in the normal area NA. In other words, as the light emitting layer EL is discontinuously present in the first rough pattern RP1, the permeation path of moisture can be lengthened, and the moisture introduced into the light emitting layer EL can be prevented from spreading to the normal area NA.

In this case, the height of the mountain can differ in the inner side rough pattern IRP and the outer side rough pattern ORP. The height of the mountain in the inner side rough pattern IRP can be larger than the height of the mountain in the outer side rough pattern ORP. As an example, the height of the mountain in the inner side rough pattern IRP may be also smaller than, or equal to the height of the mountain in the outer side rough pattern ORP.

The difference in the height of the mountain between the inner side rough pattern IRP and the outer side rough pattern ORP can come from the difference in the interlayer insulation film (e.g., ILD1, ILD2-1, or ILD2-2) included in the mountain between the inner side rough pattern IRP and the outer side rough pattern ORP.

For another example, the mountain of the inner side rough pattern IRP can include the 2-2th interlayer insulation film ILD2-2 but may not include the 2-1th inter-layer insulation film ILD2-1 and the first inter-layer insulation film ILD1.

For another example, the mountain of the outer side rough pattern ORP can include the 2-1th interlayer insulation film ILD2-1 and the first inter-layer insulation film ILD1 but may not include the 2-2th interlayer insulation film ILD2-2.

As another example, the bottom surface of the valley positioned in the outer side rough pattern ORP can be positioned lower than the bottom surface of the valley positioned in the inner side rough pattern IRP. As an example, the bottom surface of the valley positioned in the outer side rough pattern ORP may be positioned higher than or flush to the bottom surface of the valley positioned in the inner side rough pattern IRP.

For example, in the outer side rough pattern ORP, the valley can be one formed as at least a portion (e.g., the 2-1th interlayer insulation film ILD2-1) of the first interlayer insulation film ILD1 and the second interlayer insulation film ILD2 is removed.

In the process of forming the valley of the rough pattern RP by removing the first inter-layer insulation film ILD1 from the outer side rough pattern ORP, the gate insulation film GI can be damaged, or the gate insulation film (e.g., ABUF or MBUF) positioned under the gate insulation film GI can be damaged.

Accordingly, the metal pattern can be further disposed in the valley positioned in the outer side rough pattern ORP. In this case, the metal pattern having the same shape as the valley positioned in the outer side rough pattern ORP can be disposed in the surrounding area SA. The metal pattern positioned corresponding to the valley of the outer side rough pattern ORP can function as an “etching stopper.”

Alternatively, the metal pattern can be positioned to overlap the mountain positioned on the outer side rough pattern ORP. In other words, the metal pattern can be widely positioned under the outer side rough pattern ORP. In this case, the metal pattern can also minimize or prevent the micro-cracks generated in the through hole TH from spreading to the normal area NA. In this case, the metal pattern can function not only as an etching stopper but also as a crack stopper.

The metal pattern is formed of the same material as the gate material layer GM and can be positioned on the gate insulation film GI. As an examiner, the metal pattern may be formed of a material different from that of the gate material layer GM. As an example, the metal pattern may be positioned on a layer different from the gate insulation film GI. As an example, the metal pattern may be omitted depending on the design.

In the surrounding area SA of the optical electronic device11, the anode electrode or cathode electrode may not be formed on the lower and upper sides of the light emitting layer EL.

Accordingly, the encapsulation layer ENCAP can be disposed on the light emitting layer EL of the surrounding area SA. The encapsulation layer ENCAP can include a first encapsulation layer PAS1, a second encapsulation layer PCL, and a third encapsulation layer PAS2.

In the surrounding area SA, an encapsulation layer ENCAP composed of a first encapsulation layer PAS1, a second encapsulation layer PCL, and a third encapsulation layer PAS2 can be formed on the light emitting layer EL.

A touch buffer film T-BUF can be disposed on the encapsulation layer ENCAP.

A second rough pattern RP2 can be formed on the outer side rough pattern ORP of the surrounding area SA to block moisture introduced from the outside or through the through hole TH.

The second rough pattern RP2 can include a bridge metal BRG and a touch sensor metal TSM constituting a touch sensor TS.

The touch sensor metal TSM and the bridge metal BRG can be formed of a triple structure of Ti/Al/Ti.

A bridge metal BRG including a disconnected area with a predetermined interval can be formed on the touch buffer film T-BUF.

A touch interlayer insulation film T-ILD can be disposed over the bridge metal BRG to be separate to open the disconnected area. Therefore, the disconnected area of the bridge metal BRG can be exposed between the spaced sections of the touch interlayer insulation film T-ILD.

In this case, to enhance touch performance, the touch interlayer insulation film T-ILD can be formed of an organic material of silicon oxide SiOx.

The touch sensor metal TSM can be disposed to cover the disconnected area of the bridge metal BRG and the touch interlayer insulation film T-ILD.

In this case, the touch sensor metal TSM can have a disconnected area formed on an upper portion of the touch interlayer insulation film T-ILD. Therefore, the spaced sections of the touch sensor metal TSM can be electrically connected to each other by the disconnected area.

In this case, when the touch sensor TS is formed on the display panel 110, moisture can be introduced through the encapsulation layer ENCAP from the chemical solution (e.g., developer or etchant) used in the process or from the outside or, moisture can enter the encapsulation layer ENCAP through the through hole TH where the optical electronic device 11 is positioned.

However, the display panel 110 of the disclosure can block moisture from entering by the second rough pattern RP2 formed on the encapsulation layer ENCAP.

The protective layer PAC can be disposed while covering the touch sensor metal TSM. The protective layer PAC can be an organic insulation film.

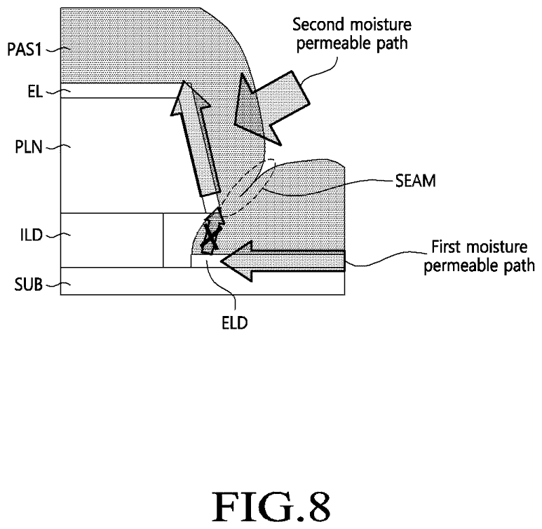

FIG. 8 is a view illustrating a moisture permeable path of moisture introduced along a first rough pattern in a display panel according to embodiments of the disclosure.

For briefly describing the moisture permeable path, the substrate SUB, multi-buffer layer MBUF, active buffer layer ABUF, and gate insulation film GI are simply illustrated as a substrate SUB.

Referring to FIG. 8, in the display panel 110 according to embodiments of the disclosure, a residual light emitting layer ELD of the same material as the light emitting layer EL and a residual cathode electrode of the same material as the cathode electrode CE can be positioned in the valley of the first rough pattern RP1.

The residual light emitting layer positioned in the valley can be disconnected without being connected to the light emitting layer EL positioned in the mountain. The residual cathode electrode positioned in a valley can be disconnected without being connected to the cathode electrode CE positioned on the mountain.

The residual cathode electrode can be further disposed on the residual light emitting layer.

Moisture introduced through the optical electronic device 11 can move to the side surface of the first rough pattern RP1 through the first moisture permeable path.

The direction in which the moisture enters the residual light emitting layer through the first moisture permeable path can be a direction from the through hole TH to the normal area NA.

Moisture penetrating into the residual light emitting layer through the first moisture permeable path can move from the end of the residual light emitting layer toward the light emitting layer EL. In this case, moisture can move along the inside of the first encapsulation layer PAS1. In other words, the moisture can move in the order of the residual light emitting layer, the first encapsulation layer PAS1, and the light emitting layer EL.

In this case, the first encapsulation layer PAS1 can include a seam SEAM. The inside of the seam SEAM can be empty or can be filled with a material different from that of the first encapsulation layer PAS1.

The moisture moving from the residual light emitting layer to the first encapsulation layer PAS1 can move around the seam SEAM to the light emitting layer EL.

Meanwhile, the seam SEAM of the first rough pattern RP1 can include an opening positioned in the surface direction of the first encapsulation layer PAS1.

Accordingly, moisture can move around the seam SEAM inside the first encapsulation layer PAS1 to the light emitting layer EL. Accordingly, the movement path of moisture in the first encapsulation layer PAS1 can be further lengthened.

However, since the light emitting layer EL and the residual light emitting layer are disconnected by the first rough pattern RP1, the display panel 110 of the disclosure can minimize or prevent moisture introduced through the first moisture permeable path from moving to the normal area NA.

Further, moisture introduced through a chemical liquid (such as a developer or etchant) used in the process of forming the touch sensor TS on the display panel 110 or through the through hole TH can move to the light emitting layer EL through the first encapsulation layer PAS1. This can be referred to as a second moisture permeable path.

The ingress of moisture through the second moisture permeable path can further increase when the touch interlayer insulation film T-ILD or the touch buffer film T-BUF is formed of an organic material to enhance touch performance.

The display panel 110 of the disclosure can have a second rough pattern RP2 capable of minimizing or preventing ingress of moisture through the second moisture permeable path.

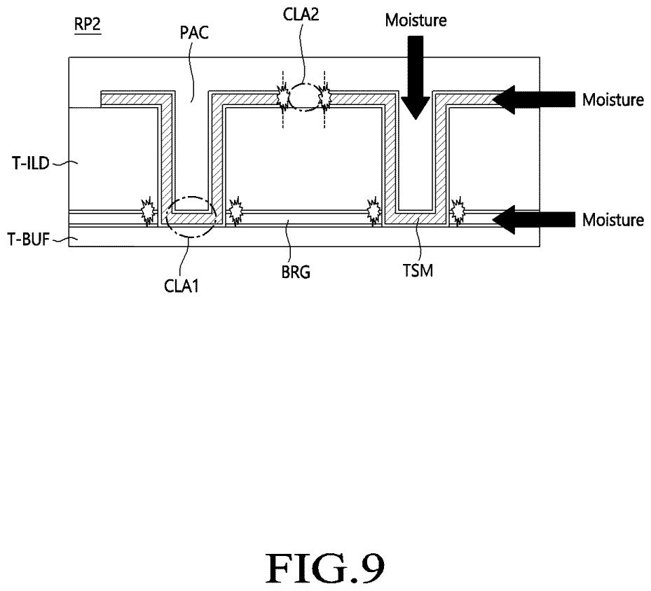

FIG. 9 is a view schematically illustrating a structure of a second rough pattern for blocking moisture introduced through a second moisture permeable path in a display panel according to embodiments of the disclosure.

Referring to FIG. 9, the second rough pattern RP2 can be positioned over the outer side rough pattern ORP constituting the first rough pattern RP1. As an example, the second rough pattern RP2 may be positioned to overlap at least a portion of the outer side rough pattern ORP, without being limited thereto. As an example, the second rough pattern RP2 may be positioned to not overlap the outer side rough pattern ORP, without being limited thereto.

A touch buffer film T-BUF can be formed on an upper portion of the first rough pattern RP1 to cover the first encapsulation layer PAS1.

The second rough pattern RP2 can be formed in a grid structure of the touch sensor metal TSM and the bridge metal BRG constituting the touch sensor TS.

For example, the bridge metal BRG and the touch interlayer insulation film T-ILD can be stacked in an island pattern having disconnected areas CLA1 and CLA2 at a predetermined interval above the touch buffer film T-BUF.

The touch sensor metal TSM can be formed to have a predetermined thickness along the first disconnected area CLA1 of the bridge metal BRG and the touch interlayer insulation film T-ILD. In this case, the touch sensor metal TSM can contact the touch buffer film T-BUF in the first disconnected area CLA1 to form a partition wall. Further, the touch sensor metal TSM can be disconnected over the touch interlayer insulation film T-ILD, leaving the second disconnected area CLA2.

The protective layer PAC can be disposed to cover the touch sensor metal TSM. The protective layer PAC can be an organic insulation film. As an example, the protective layer PAC may be filled in the first disconnected area CLA1 on the touch sensor metal TSM. As an example, the protective layer PAC may cover the touch sensor metal TSM located at the bottom of the first disconnected area CLA1, without being limited thereto.

In this case, moisture introduced through a chemical liquid (such as a developer or etchant) used in the process of forming the touch sensor TS on the display panel 110 or through the through hole TH can enter through the protective layer PAC or the touch interlayer insulation film T-ILD.

As such, moisture introduced through the second moisture permeable path can move along the touch sensor metal TSM or the bridge metal BRG.

However, in the display panel 110 of the disclosure, the touch sensor metal TSM separates the bridge metal BRG through the first disconnected area CLA1, and the area contacting the bridge metal BRG is disposed in a grid structure that forms a partition wall.

Therefore, the moisture introduced through the bridge metal BRG can be blocked from moving by the touch sensor metal TSM formed in a partition wall structure in the first disconnected area CLA1 of the bridge metal BRG.

Further, moisture introduced along the touch sensor metal TSM can be blocked from moving in the second disconnected area CLA2 positioned over the touch interlayer insulation film T-ILD.

In particular, the touch sensor metal TSM and the bridge metal BRG can have a triple stacked structure of Ti/Al/Ti. In this case, the titanium Ti, aluminum Al, and titanium Ti layers of the bridge metal BRG can contact titanium Ti of the touch sensor metal TSM formed in the partition wall structure in the vertical direction.

Therefore, moisture introduced along the aluminum Al of the bridge metal BRG can be blocked from moving due to the titanium Ti structure of the touch sensor metal TSM in the first disconnected area CLA1.

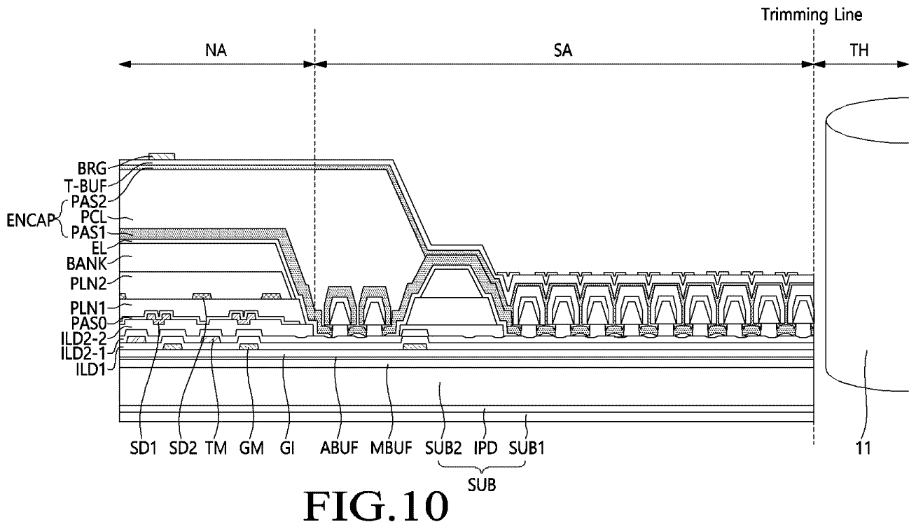

FIGS. 10 to 13 are views illustrating a process of forming a second rough pattern in a display panel according to embodiments of the disclosure.

First, referring to FIG. 10, in the display panel 110 according to embodiments of the disclosure, a second rough pattern RP2 can be formed on an upper portion of the outer side rough pattern ORP constituting the first rough pattern RP1 in order to block moisture introduced from the upper portion through the second moisture permeable path.

The emission layer EL can be positioned in at least a partial area on the first rough pattern RP1. The light emitting layer EL can be an organic light emitting layer including an organic material.

The light emitting layer EL can extend from the normal area NA to at least a partial area of the surrounding area SA. The light emitting layer EL is discontinuously positioned in the inner side rough pattern IRP and the outer side rough pattern ORP.

In the surrounding area SA of the optical electronic device11, the anode electrode or cathode electrode may not be formed on the lower and upper sides of the light emitting layer EL.

The encapsulation layer ENCAP can be disposed on the light emitting layer EL of the surrounding area SA. The encapsulation layer ENCAP can include a first encapsulation layer PAS1, a second encapsulation layer PCL, and a third encapsulation layer PAS2.

A touch buffer film T-BUF can be disposed on the encapsulation layer ENCAP.

A second rough pattern RP2 can be formed on the outer side rough pattern ORP of the surrounding area SA to block moisture introduced from the outside or through the through hole TH.

To that end, a bridge metal BRG can be formed on the touch buffer film T-BUF and etched at a predetermined interval to form a disconnected area.

In this case, the bridge metal BRG can have a triple structure of Ti/Al/Ti. As an example, the bridge metal BRG may include a conductive material other than Ti/Al/Ti, without being limited thereto.

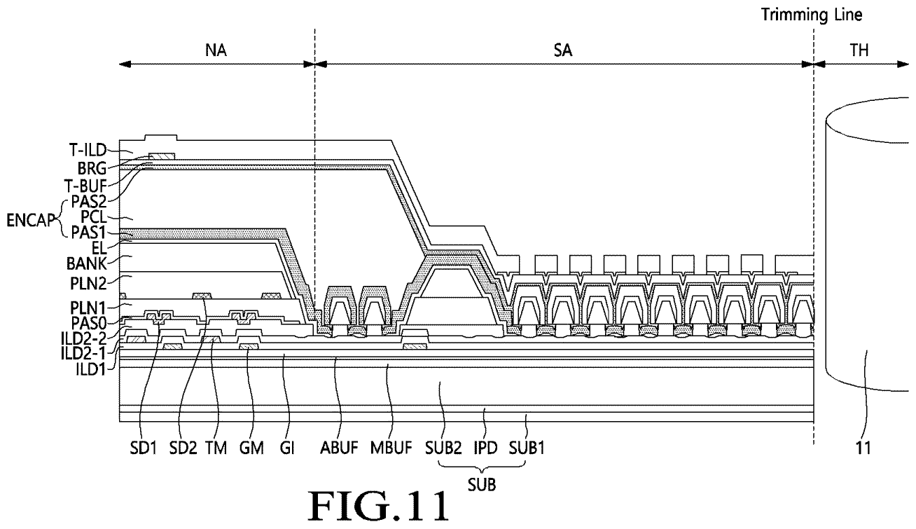

Next, referring to FIG. 11, a touch interlayer insulation layer T-ILD is formed over the bridge metal BRG so that the disconnected area of the bridge metal BRG is open.

To that end, after the touch interlayer insulation layer T-ILD is formed on the bridge metal BRG, the portion where the disconnected area of the bridge metal BRG is positioned is etched to open the disconnected area of the bridge metal BRG. As an example, at least a portion or the entirety of the disconnected area of the bridge metal BRG may be exposed by an opening of the touch interlayer insulation layer T-ILD. As an example, a portion of the bridge metal BRG may be exposed or may not be exposed by the opening of the touch interlayer insulation layer T-ILD, without being limited thereto.

In this case, to enhance touch performance, the touch interlayer insulation film T-ILD can be formed of an organic material of silicon oxide SiOx.

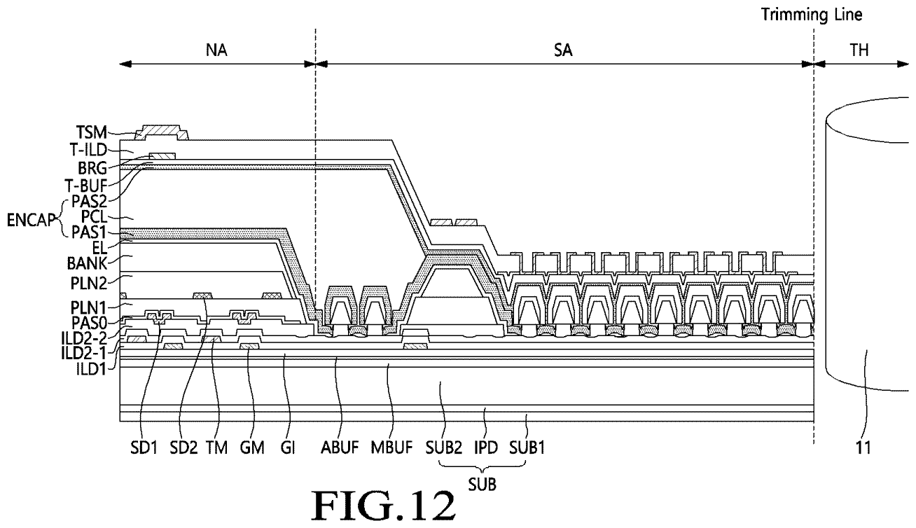

Then, referring to FIG. 12, a touch sensor metal TSM is formed to cover a portion of the touch interlayer insulation film T-ILD and the disconnected area of the bridge metal BRG.

In this case, a partial area of the touch sensor metal TSM can be etched so that the disconnected area is formed over the touch interlayer insulation film T-ILD. Therefore, the spaced sections of the touch sensor metal TSM can be electrically connected to each other by the disconnected area. As an example, the touch sensor metal TSM filled in the opening of the touch interlayer insulation layer T-ILD may be in contact with the bridge metal BRG under the touch interlayer insulation layer T-ILD. As an example, the touch sensor metal TSM filled in the opening of the touch interlayer insulation layer T-ILD may be in contact with the bridge metal BRG under the touch interlayer insulation layer T-ILD at both sides of the opening of the touch interlayer insulation layer T-ILD.

In this case, since the touch sensor metal TSM contacts the disconnected area of the bridge metal BRG to form a partition wall, the movement of moisture introduced through the bridge metal BRG can be blocked.

Further, since the touch sensor metal TSM has a disconnected area formed above the touch interlayer insulation layer T-ILD, the movement of moisture introduced through the touch sensor metal TSM can be blocked.

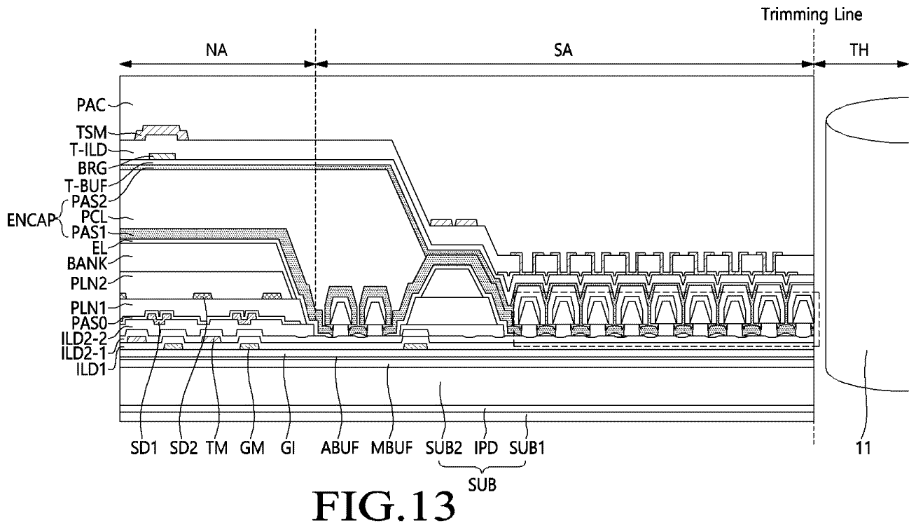

Referring to FIG. 13, the protective layer PAC can be disposed to cover the normal area NA and the surrounding area SA. The protective layer PAC can be an organic insulation film.

As such, since the second rough pattern RP2 including the touch sensor metal TSM and the bridge metal BRG disposed in a grid structure is formed on the encapsulation layer ENCAP of the surrounding area SA, the movement of moisture introduced along the second moisture permeable path through the upper portion or through hole TH can be blocked.

Meanwhile, the display panel 110 of the disclosure can omit the touch interlayer insulation film T-ILD between the bridge metal BRG and the touch sensor metal TSM in the process of forming the second rough pattern RP2.

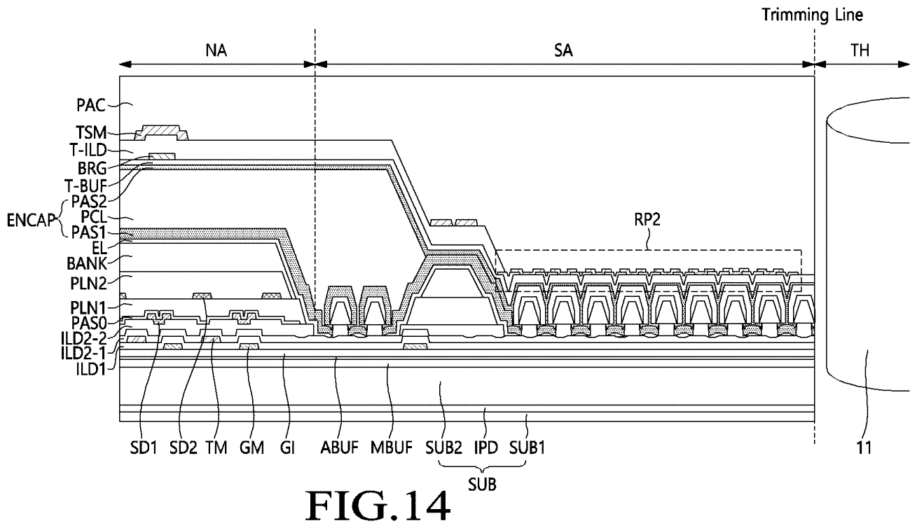

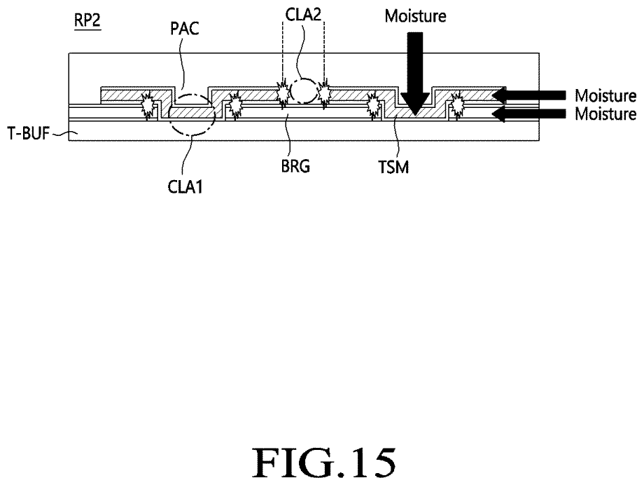

FIG. 14 is a view illustrating an example of another structure of an optical area in a display panel according to embodiments of the disclosure. FIG. 15 is a view schematically illustrating another structure of a second rough pattern for blocking moisture introduced through a second moisture permeable path in a display panel according to embodiments of the disclosure.

Referring to FIGS. 14 and 15, the second rough pattern RP2 can be positioned over the outer side rough pattern ORP constituting the first rough pattern RP1.

A touch buffer film T-BUF can be formed over the first rough pattern RP1 to cover the encapsulation layer ENCAP.

The second rough pattern RP2 can be formed in a grid structure of the touch sensor metal TSM and the bridge metal BRG constituting the touch sensor TS.

For example, the bridge metal BRG can be stacked in an island pattern having a first disconnected area CLA1 at a predetermined interval above the touch buffer film T-BUF.

Further, the touch sensor metal TSM can be formed to cover a portion of the upper portion of the bridge metal BRG and the first disconnected area CLA1. In this case, the touch interlayer insulation film T-ILD can be formed up to the normal area NA and the inner side rough pattern IRP, but is not formed on the upper portion of the outer side rough pattern ORP where the second rough pattern RP2 is positioned.

In this case, the touch sensor metal TSM can contact the touch buffer film T-BUF in the first disconnected area CLA1 of the bridge metal BRG, and can form a partition wall for the bridge metal BRG. Further, the touch sensor metal TSM can be separated from the upper portion of the bridge metal BRG with respect to the second disconnected area CLA2.

The protective layer PAC can be disposed to cover the touch sensor metal TSM. The protective layer PAC can be an organic insulation film.

As described above, in the display panel 110 of the disclosure, the touch sensor metal TSM is separated through the second disconnected area CLA2, and is disposed in a grid structure to contact the bridge metal BRG in the first disconnected area CLA1 forming a partition wall.

Therefore, moisture introduced along the touch sensor metal TSM can be blocked from moving in the second disconnected area CLA2 positioned over the bridge metal BRG.

Further, the moisture introduced through the bridge metal BRG can be blocked from moving by the touch sensor metal TSM formed in a partition wall structure in the first disconnected area CLA1 of the bridge metal BRG.

In particular, the touch sensor metal TSM and the bridge metal BRG can have a triple stacked structure of Ti/Al/Ti. In this case, the titanium Ti, aluminum Al, and titanium Ti layers of the bridge metal BRG can contact titanium Ti of the touch sensor metal TSM formed in the partition wall structure in the vertical direction.

Therefore, moisture introduced along the aluminum Al of the bridge metal BRG can be blocked from moving due to the titanium Ti structure of the touch sensor metal TSM in the first disconnected area CLA1.

Embodiments of the disclosure described above are summarized as follows.

A display device according to aspects of the disclosure can comprise a display panel including a through hole in a display area, an optical electronic device positioned to at least partially overlap the through hole, and a driving circuit controlling the display panel. The display panel can include a first rough pattern capable of blocking moisture introduced along a first moisture permeable path in a surrounding area of the through hole, and a second rough pattern disposed to overlap at least a portion of the first rough pattern to block moisture introduced along a second moisture permeable path.

The display panel can include a light emitting layer commonly positioned in at least a partial area of the display area. The light emitting layer can be disconnected along the first rough pattern.

The display area can include an optical area where the through hole, the first rough pattern, and the second rough pattern are positioned, and a normal area where a subpixel is positioned outside the optical area. The first rough pattern can include an outer side rough pattern positioned in an area adjacent to the through hole, and an inner side rough pattern positioned in an area adjacent to the normal area.

The display panel can include a substrate, and an interlayer insulation film positioned on the substrate and covering at least one electrode. The first rough pattern can be positioned in an area where at least a portion of the interlayer insulation film is removed.

The first rough pattern can include a mountain including the interlayer insulating film, and a valley where at least a portion of the interlayer insulation film is removed. The light emitting layer can be disconnected between the mountain and the valley.

The display panel can further include an encapsulation layer and a touch buffer film disposed to cover the first rough pattern. The second rough pattern can be formed over the touch buffer film to overlap at least a portion of the outer side rough pattern.

The second rough pattern can include a bridge metal formed to be spaced apart from a first disconnected area separated at a predetermined interval, and a touch sensor metal disposed to cover the first disconnected area and having a second disconnected area separated at a predetermined interval over the bridge metal.

The display panel can further include a touch interlayer insulation film formed over the bridge metal. The second disconnected area of the touch sensor metal can be positioned over the touch interlayer insulation film.

The bridge metal and the touch sensor metal can be formed of a triple metal layer of titanium (Ti)/aluminum (Al)/titanium (Ti).

The aluminum metal layer of the bridge metal can contact the titanium metal layer of the touch sensor metal in the first disconnected area.

A display panel according to aspects of the disclosure can comprise a through hole where an optical electronic device is disposed in a display area, a first rough pattern capable of blocking moisture introduced along a first moisture permeable path in a surrounding area of the through hole, and a second rough pattern disposed to overlap at least a portion of the first rough pattern to block moisture introduced along a second moisture permeable path.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

What is claimed is:

1. A display device, comprising:
a display panel including a through hole in a display area;
a driving circuit configured to control the display panel,
wherein the display panel further includes:
a first rough pattern formed in a surrounding area of the through hole.

2. The display device of claim 1, wherein the display panel includes a light emitting layer commonly positioned in at least a partial area of the display area, and
wherein the light emitting layer is disconnected along the first rough pattern.

3. The display device of claim 2, wherein the display area includes:
an optical area where the through hole and the first rough pattern are positioned; and
a normal area where a subpixel is positioned outside the optical area, and
wherein the first rough pattern includes:
an outer side rough pattern positioned in an area adjacent to the through hole; and
an inner side rough pattern positioned in an area adjacent to the normal area.

4. The display device of claim 3, further comprising an encapsulation layer disposed to cover the first rough pattern, and
a dam configured to separate the inner side rough pattern and the outer side rough pattern, and to block overflowing of the encapsulation layer toward the through hole.

5. The display device of claim 1, wherein the display panel includes:
a substrate; and
an interlayer insulation film positioned on the substrate and covering at least one electrode, and
wherein the first rough pattern is positioned in an area where at least a portion of the interlayer insulation film is removed.

6. The display device of claim 5, wherein the first rough pattern includes:
a mountain part including the interlayer insulating film; and
a valley part where at least a portion of the interlayer insulation film is removed, and
wherein the light emitting layer is disconnected between the mountain part and the valley part.

7. The display device of claim 6, a portion of the light emitting layer positioned on the mountain part is disconnected from a portion of the light emitting layer positioned in the valley part.

8. The display device of claim 1, further comprising:
a second rough pattern disposed to overlap at least a portion of the first rough pattern.

9. The display device of claim 8, wherein the display panel further includes an encapsulation layer and a touch buffer film disposed to cover the first rough pattern, and
wherein the second rough pattern is formed over the touch buffer film to overlap at least a portion of an outer side rough pattern of the first rough pattern.

10. The display device of claim 9, wherein the second rough pattern includes:
a bridge metal formed to be spaced apart from a first disconnected area separated at a predetermined interval; and
a touch sensor metal disposed to cover the first disconnected area and having a second disconnected area separated at a predetermined interval over the bridge metal.

11. The display device of claim 10, wherein the display panel further includes a touch interlayer insulation film formed over the bridge metal, and
wherein the second disconnected area of the touch sensor metal is positioned over the touch interlayer insulation film.

12. The display device of claim 11, wherein the bridge metal and the touch interlayer insulation film are stacked in an island pattern having the first disconnected area.

13. The display device of claim 10, wherein the bridge metal and the touch sensor metal include a triple metal layer of titanium (Ti)/aluminum (Al)/titanium (Ti).

14. The display device of claim 13, wherein an aluminum metal layer of the bridge metal contacts a titanium metal layer of the touch sensor metal in the first disconnected area.

15. The display device of claim 10, wherein the touch sensor metal contacts the touch buffer film in the first disconnected area to form a partition wall.

16. The display device of claim 2, wherein the first rough pattern has a structure of blocking moisture introduced through the light emitting layer.

17. The display device of claim 6, wherein the second rough pattern has a structure of blocking moisture introduced through the encapsulation layer.

18. The display device of claim 1, further comprising:
an optical electronic device positioned to at least partially overlap the through hole.

19. A display panel, comprising:
a display area including a through hole;
a first rough pattern disposed in a surrounding area of the through hole; and
a second rough pattern disposed to overlap at least a portion of the first rough pattern.

20. A display panel, comprising:
a display area including a through hole;
an encapsulation layer and a touch buffer film over the encapsulation layer extending to a surrounding area of the through hole,
a first rough pattern formed in the surrounding area over the touch buffer film.
